(19) United States
(12) Patent Application Publication
(10) Pub. No.: US 2025/0048788 A1
(43) Pub. Date: Feb. 6, 2025

(54) LIGHT EMITTING ELEMENT

(71) Applicant: NICHIA CORPORATION, Anan-shi (JP)

(72) Inventor: Koji FUJIMOTO, Anan-shi (JP)

(73) Assignee: NICHIA CORPORATION, Anan-shi (JP)

(21) Appl. No.: 18/775,453

(22) Filed: Jul. 17, 2024

(30) Foreign Application Priority Data
Jul. 31, 2023 (JP) 2023-124605

(51) Int. Cl. H01L 33/10; H01L 33/24; H01L 33/30

(52) U.S. Cl. CPC H01L 33/10; H01L 33/24; H01L 33/30

(57) ABSTRACT

A light emitting element includes: a conductive member having a first through hole; a reflecting layer disposed in the first through hole; an insulation layer disposed on the conductive member and the reflecting layer and having second through holes positioned so as not to overlap the first through hole in a plan view; a semiconductor structure including a p-type semiconductor layer disposed on the insulation layer, an emission layer disposed on the p-type semiconductor layer, and an n-type semiconductor layer disposed on the emission layer in part; an n-electrode disposed on and electrically connected to the n-type semiconductor layer; and p-electrode electrically connected to the conductive member. A reflectance of the reflecting layer for a peak wavelength of light emitted from the emission layer is higher than the reflectance of the conductive member for the peak wavelength of the light emitted from the emission layer.

### CROSS-REFERENCE TO RELATED APPLICATIONS

This application is based upon and claims priority to Japanese Patent Application No. 2023-124605, filed on Jul. 31, 2023, the entire contents of which are incorporated herein by reference.

### FIELD

An embodiment of the present invention relates to a light emitting element.

### BACKGROUND

A light emitting element having a structure in which a conductive member is provided under a semiconductor structure, including an emission layer, to allow the conductive member to reflect the light from the emission layer upward has been known. See, for example, Japanese Patent Publication No. 2014-138007. Such a structure, however, allows the conductive member to absorb a portion of the outgoing light from the emission layer, reducing the light extraction efficiency. There is a need to improve the light extraction efficiency of such a light emitting element.

### SUMMARY

An embodiment of the present invention aims to provide a light emitting element with improved light extraction efficiency.

A light emitting element according to one embodiment of the present invention includes a conductive member, a reflecting layer, an insulation layer, a semiconductor structure, an n-electrode, and p-electrode. The conductive member has a first through hole. The reflecting layer is disposed in the first through hole. The insulation layer is disposed on the conductive member and the reflecting layer. The insulation layer has a second through hole. The second through hole is positioned so as not to overlap the first through hole in a plan view. The semiconductor structure has a p-type semiconductor layer, an emission layer, and an n-type semiconductor layer. The p-type semiconductor layer is disposed on the insulation layer. The emission layer is disposed on the p-type semiconductor layer. The n-type semiconductor layer is disposed on the emission layer in part. The n-electrode is disposed on the n-type semiconductor layer. The n-electrode is connected to the n-type semiconductor layer. The p-electrode is connected to the conductive member. The reflectance of the reflecting layer for the peak wavelength of the light from the emission layer is higher than the reflectance of the conductive member for the peak wavelength of the light from the emission layer. A portion of the conductive member is in contact with the p-type semiconductor layer in the second through hole. In a plan view, at least one portion of the reflecting layer overlaps the emission layer.

According to one embodiment of the present invention, a light emitting element with improved light extraction efficiency can be realized.

### BRIEF DESCRIPTION OF THE DRAWINGS

FIG. 1 is a plan view schematically showing a light emitting element according to an embodiment.

FIG. 2 is a plan view schematically showing a layout of the conductive member and the reflecting layer of the light emitting element according to the embodiment.

FIG. 3 is a cross-sectional view schematically showing the light emitting element according to the embodiment.

FIG. 4 is an enlarged cross-sectional view schematically showing a portion of the light emitting element according to the embodiment.

FIG. 5 is a plan view schematically showing a layout of the conductive member and the reflecting layer of a light emitting element in a first variation of the embodiment.

FIG. 6 is a cross-sectional view schematically showing the light emitting element in the first variation of the embodiment.

FIG. 7 is a plan view schematically showing a layout of the conductive member and the reflecting layer of a light emitting element in a second variation of the embodiment.

FIG. 8 is a plan view schematically showing a layout of the conductive member and the reflecting layer of a light emitting element in a third variation of the embodiment.

FIG. 9 is a plan view schematically showing a layout of the conductive member and the reflecting layer of a light emitting element in a fourth variation of the embodiment.

FIG. 10 is a plan view schematically showing a layout of the conductive member and the reflecting layer of a light emitting element in a fifth variation of the embodiment.

FIG. 11 is a cross-sectional view schematically showing the light emitting element in the fifth variation of the embodiment.

FIG. 12 is a cross-sectional view schematically showing a method of manufacturing a light emitting element according to one embodiment.

FIG. 13 is a cross-sectional view schematically showing the method of manufacturing a light emitting element according to the embodiment.

FIG. 14 is a cross-sectional view schematically showing the method of manufacturing a light emitting element according to the embodiment.

FIG. 15 is a cross-sectional view schematically showing the method of manufacturing a light emitting element according to the embodiment.

FIG. 16 is a cross-sectional view schematically showing the method of manufacturing a light emitting element according to the embodiment.

FIG. 17 is a cross-sectional view schematically showing the method of manufacturing a light emitting element according to the embodiment.

### DETAILED DESCRIPTION

Certain embodiments of the present invention will be explained below with reference to the accompanying drawings.

Each drawing is schematic or conceptual. Therefore, the relationship between the thickness and the width of each member, the dimensional ratio of constituent elements, and the like, might not necessarily be the same as those in an actual product. Depending on the drawing, the same portion or part might be depicted using a different size or dimensional ratio.

In the present specification and the drawings, elements already explained are denoted with the same reference numerals, and repeated detailed descriptions thereof are omitted as appropriate.

In the following description, moreover, the layout and the structure of each part or portion are described by using an XYZ orthogonal coordinate system to make the explanation easily understood. The X, Y, and Z axes are orthogonal to one another. The direction in which the X axis extends is designated as the “X direction,” the direction in which the Y axis extends is designated as the “Y direction,” and the direction in which the Z axis extends is designated as the “Z direction.” To make the explanation easily understood, the direction of the Z direction indicated by the arrow may also be referred to as the upward direction, and the opposite direction may be referred to as the downward direction. These directions are irrespective of the direction of gravity. Furthermore, a view of an object in the Z direction is referred to as a plan view of the object.

### Light Emitting Element

FIG. 1 is a plan view schematically showing a light emitting element according to an embodiment.

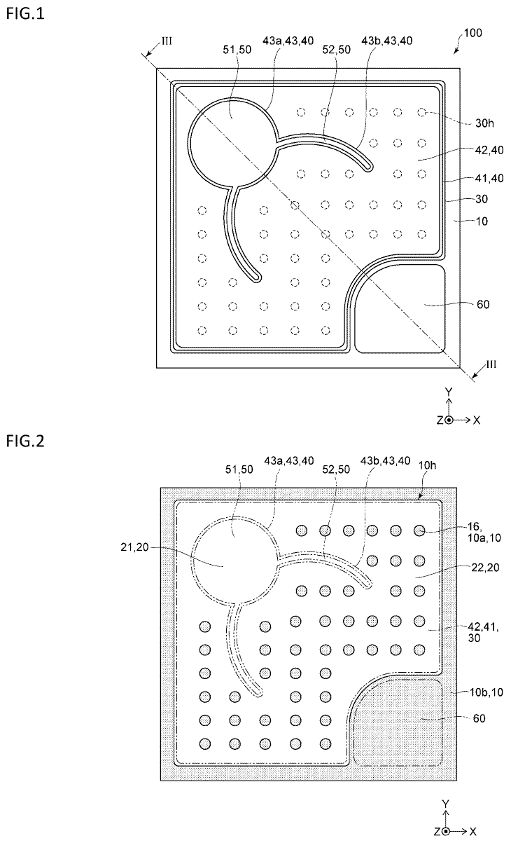

FIG. 2 is a plan view schematically showing a layout of the conductive member and the reflecting layer of the light emitting element according to the embodiment.

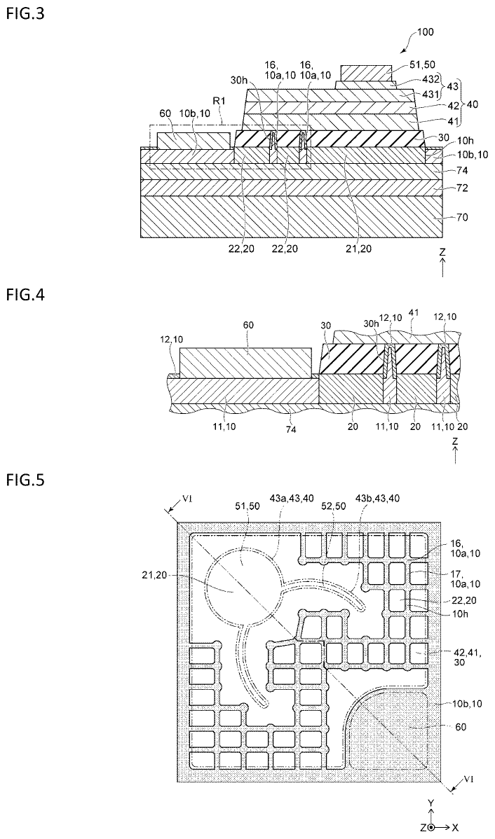

FIG. 3 is a cross-sectional view schematically showing the light emitting element according to the embodiment.

FIG. 4 is an enlarged cross-sectional view schematically showing a portion of the light emitting element according to the embodiment.

FIG. 3 is a cross-sectional view taken along line III-III in FIG. 1.

FIG. 4 is an enlarged view of the region R1 in FIG. 3.

As illustrated in FIG. 1 to FIG. 4, a light emitting element 100 according to an embodiment includes a conductive member 10, a reflecting layer 20, an insulation layer 30, a semiconductor structure 40, an n-electrode 50, and a p-electrode 60.

### Conductive Member

A conductive member 10 is disposed under the insulation layer 30. The conductive member 10 has a first conductive layer 11 and a second conductive layer 12. The second conductive layer 12 is disposed on the first conductive layer 11. The second conductive layer 12 is in contact with the upper face of the first conductive layer 11, covering the upper face of the first conductive layer 11. A portion of the second conductive layer 12 is disposed between the first conductive layer 11 and the insulation layer 30. Another portion of the second conductive layer 12 is disposed between the first conductive layer 11 and the p-type semiconductor layer 41. The second conductive layer 12 is in contact with the p-type semiconductor layer 41. The second conductive layer 12 is electrically connected to the p-type semiconductor layer 41. The plan view shape of the conductive member 10 is, for example, quadrangular. The upper face and the lower face of the conductive member 10 are generally parallel to the X-Y plane, except for the portion that is disposed in the second through hole 30h described below.

The second conductive layer 12 has only to be disposed on the first conductive layer 11 at least in part. In other words, the second conductive layer 12 does not have to be disposed on a portion of the first conductive layer 11. No second conductive layer 12 is disposed between the first conductive layer 11 and the p-electrode 60. The first conductive layer 11 is in contact with the p-electrode 60. The first conductive layer 11 is electrically connected to the p-electrode 60.

The conductive member 10 has a first through hole 10h. The first through hole 10h goes through the conductive member 10 in the Z direction. The plan view shape of a first through hole 10h is circular. In the case in which the plan view shape of the first through hole 10h is circular, the diameter of the first through hole 10h is in a range of 10 μm to 20 μm.

The conductive member 10 has a first region 10a and a second region 10b. The first region 10a overlaps the semiconductor structure 40 in a plan view. The second region 10b does not overlap the semiconductor structure 40 in a plan view. The p-electrode 60 is disposed on the second region 10b. In other words, the p-electrode 60 is disposed at a location that does not overlap the semiconductor structure 40 in a plan view. The p-electrode 60 may be disposed in the first region 10a. In other words, the p-electrode 60 may be disposed at a location that overlaps the semiconductor structure 40 in a plan view.

The first region 10a of the conductive member 10 has a plurality of first portions 16. The first portions 16 overlap the second through holes 30h in a plan view. The first portions 16 are located in the second through holes 30h in part. The plan view shape of a first portion 16 is circular. The plan view shape of a first portion 16 may be, for example, polygonal. In the case in which the plan view shape of a first portion 16 is circular, the diameter of the first portion 16 is in a range of 10 μm to 20 μm. The areas of the first portions 16 are the same in a plan view. The areas of the first portions 16 in a plan view do not have to be the same.

The first region 10a of the conductive member 10 is provided only at locations that overlap the second through holes 30h in a plan view. Providing the first region 10a of the conductive member 10 only at locations that overlap the second through holes 30 can reduce the absorption of light by the conductive member 10, thereby improving the light extraction efficiency.

The first region 10a of the conductive member 10 is provided only at locations that do not overlap the n-electrode 50 and the n-type semiconductor layer 43 in a plan view. Providing the first region 10a of the conductive member 10 only at locations that do not overlap the n-electrode 50 and the n-type semiconductor layer 43 can reduce the absorption of light by the conductive member 10, thereby improving the light extraction efficiency.

The conductive member 10 includes a conducting material such as a metal. For the first conductive layer 11, for example, gold, silver, copper, aluminum, rhodium, ruthenium, or the like can be used. The first conductive layer 11 includes, for example, gold. The thickness of the first conductive layer 11 is, for example, in a range of 300 nm to 400 nm. For the second conductive layer 12, for example, indium tin oxide, indium zinc oxide, gallium zinc oxide, aluminum zinc oxide, or the like can be used. The second conductive layer 12 includes, for example, indium tin oxide. The thickness of the second conductive layer 12 is, for example, in a range of 100 nm to 200 nm.

### Reflecting Layer

A reflecting layer 20 is disposed in the first through hole 10h. The reflecting layer 20 is in contact with the conductive member 10. In a plan view, the reflecting layer 20 is disposed in each region where the first through hole 10h is provided.

The reflecting layer 20 is, for example, a multilayer dielectric film. The reflecting layer 20 is a multilayer dielectric film having, for example, a layer made of silicon dioxide and a layer made of niobium oxide. The reflecting layer 20 may include, for example, titanium oxide or the like. The thickness of the reflecting layer 20 is, for example, in a range of 500 nm to 1000 nm.

The reflectance of the reflecting layer 20 for the peak wavelength of the light from the emission layer 42 is higher than the reflectance of the conductive member 10 for the peak wavelength of the light from the emission layer 42. The reflectance of the reflecting layer 20 for the peak wavelength of the light from the emission layer 42 is, for example, 70% or higher, preferably 80% or higher. The reflectance of the conductive member 10 for the peak wavelength of the light from the emission layer 42 is, for example, 60% or higher, preferably 70% or higher. The reflectance value is measured by using, for example, an absolute reflectance measurement system. For the absolute reflectance measurement system, for example, a “Shimadzu Absolute Reflectance Measurement System” can be used.

Furthermore, at least a portion of the reflecting layer 20 is disposed at a location that overlaps the emission layer 42 in a plan view. A portion of the reflecting layer 20 may be provided at a location that does not overlap the emission layer 42 in a plan view.

Providing a reflecting layer 20 at a location that overlaps the emission layer 42 allows the reflecting layer 20 to reflect the light advancing from the emission layer 42 to the reflecting layer 20 towards the p-side semiconductor layer 41. This can increase the light extraction efficiency as compared to the case in which no reflecting layer 20 is provided.

The reflecting layer 20, moreover, has a first reflecting portion 21 and a second reflecting portion 22. The first reflecting portion 21 overlaps the n-electrode 50 in a plan view. The second reflecting portion 22 does not overlap the n-electrode 50 in a plan view.

The light from the emission layer 42 is readily blocked by the n-electrode 50 at a location that overlaps the n-electrode 50 in a plan view. Providing a reflecting layer 20 with a first reflecting portion 21 overlapping the n-electrode 50 in a plan view and a second reflecting portion 22 not overlapping the n-electrode 50 in a plan view can increase the light extraction efficiency by not only the portion where the light from the emission layer 42 is readily blocked, but also the portion where the light from the emission layer 42 is barely blocked.

### Insulation Layer

An insulation layer 30 is disposed on the conductive member 10 and the reflecting layer 20. The insulation layer 30 is in contact with the conductive member 10 and the reflecting layer 20. The thickness of the insulation layer 30 is, for example, in a range of 100 μm to 300 μm. The upper face and the lower face of the insulation layer 30 are generally parallel to the X-Y plane. The insulation layer 30 has a second through hole 30h. The second through hole 30h goes through the insulation layer 30 in the Z direction. The second through hole 30h is positioned so as not to overlap the first through hole 10h in a plan view. The second through hole 30h is positioned so as not to overlap the reflecting layer 20. In the second through hole 30h, a portion of the conductive member 10 is located.

The quantity of the second through holes 30h may be set to one, two, or more. Multiple second through holes 30h are arranged in a matrix along the X and Y directions. The layout is not limited to this, and multiple second through holes 30h may be provided in a staggard arrangement.

The insulation layer 30 includes an insulation material. The insulation layer 30 includes, for example, silicon dioxide. The insulation layer 30 may include at least either silicon nitride or silicon oxide, for example.

### Semiconductor Structure

On the insulation layer 30, a semiconductor structure 40 is disposed. The semiconductor structure 40 is in contact with the insulation layer 30. The semiconductor structure 40 has a p-type semiconductor layer 41, an emission layer 42, and an n-type semiconductor layer 43. The n-type semiconductor layer 43 includes a first layer 431 and a second layer 432 disposed partly on the first layer 431. The p-type semiconductor layer 41 is disposed on the insulation layer 30. The p-type semiconductor layer 41 is in contact with the insulation layer 30. The emission layer 42 is disposed on the p-type semiconductor layer 41. The emission layer 42 is in contact with the p-type semiconductor layer 41 and the first layer 431 of the n-type semiconductor layer 43. A portion of the conductive member 10 is in contact with the p-type semiconductor layer 41 in each second through hole 30h. In other words, the portions of the conductive member 10 disposed in the second through holes 30h are in contact with the p-type semiconductor layer 41. The upper faces and the lower faces of the p-type semiconductor layer 41, the emission layer 42, and the n-type semiconductor layer 43 are generally parallel to the X-Y plane.

The semiconductor structure 40 emits red light, for example. In this case, the p-type semiconductor layer 41 contains GaP (gallium phosphide), for example. The emission layer 42 contains, for example, AlGaInP (aluminum indium gallium phosphide) and GaInP (gallium indium phosphide). The first layer 431 of the n-type semiconductor layer 43 contains AlGaInP, for example. The second layer 432 of the n-type semiconductor layer 43 contains GaAs (gallium arsenide), for example. The p-type semiconductor layer 41, the emission layer 42, and the n-type semiconductor layer 43 are not limited to these, and can be any other semiconductor combination that emits red light. The peak wavelength of the light emitted by the emission layer 42 is, for example, in a range of 620 nm to 700 nm.

Because the band gap energy of the second layer 432 is smaller than the band gap energy of the first layer 431, the second layer 432 readily absorbs more light from the emission layer 42 than the first layer 431. Disposing the second layer 432 partly on the first layer 431 can reduce the absorption of light by the second layer 432. Considering the light absorption of the second layer 432, the thickness of the second layer 432 is preferably smaller than the thickness of the first layer 431. The thickness of the first layer 431 is, for example, in a range of 2 μm to 4 μm, and the thickness of the second layer 432 is, for example, in a range of 0.05 μm to 0.5 μm.

### N-Electrode

On the n-type semiconductor layer 43, an n-electrode 50 is disposed. The n-electrode 50 is in contact with the n-type semiconductor layer 43. The n-electrode 50 is electrically connected to the n-type semiconductor layer 43. The upper face and the lower face of the n-electrode 50 are generally parallel to the X-Y plane.

Furthermore, the n-electrode 50 has a pad portion 51 and an extended portion 52. The plan view shape of the pad portion 51 is, for example, circular. The extended portion 52 extends from the pad portion 51 in a plan view. The second layer 432 of the n-type semiconductor layer 43 has a first semiconductor portion 43a and a second semiconductor portion 43b. The first semiconductor portion 43a overlaps the pad portion 51 in a plan view. The second semiconductor portion 43b overlaps the extended portion 52 in a plan view. The first reflecting portion 21 of the reflecting layer 20 overlaps both the pad portion 51 and the extended portion 52 in a plan view.

In a plan view, in the regions where the emission layer 42 overlaps the pad portion 51 and the extended portion 52 of the n-electrode 50, the light from the emission layer 42 is readily blocked by the pad portion 51 and the extended portion 52 of the n-electrode 50. Placing the first reflecting portion 21 to overlap the pad portion 51 and the extended portion 52 in a plan view can increase the reflecting regions while reducing the emission of the portions of the emission layer 42 that overlap the pad portion 51 and the extended portion 52, thereby improving the light extraction efficiency.

The n-electrode 50 includes a conducting material such as a metal. For the n-electrode 50, for example, gold, silver, platinum, titanium, nickel, germanium, rhodium, or ruthenium can be used.

### P-Electrode

A p-electrode 60 is disposed on the portion of the conductive member 10 on which the insulation layer 30, the semiconductor structure 40, and the n-electrode 50 are absent. The p-electrode 60 is in contact with the conductive member 10. The p-electrode 60 is electrically connected to the conductive member 10. The upper face and the lower face of the p-electrode 60 are generally parallel to the X-Y plane.

The p-electrode 60 includes a conducting material such as a metal. For the p-electrode 60, for example, gold, silver, platinum, titanium, nickel, germanium, rhodium, or ruthenium can be used.

Applying a voltage across the n-electrode 50 and the p-electrode 60 allows the emission layer 42 to emit light. This allows the light emitting element 100 to emit light.

The light emitting element 100 further includes a substrate 70, a bonding member 72, and a reflecting metal layer 74. The light emitting element 100 can include or omit any the substrate 70, the bonding member 72, and the reflecting metal layer 74 as needed.

The plan view shape of the substrate 70 is, for example, quadrangular. The substrate 70 includes, for example, at least either silicon or aluminum nitride. The substrate 70 may be one that includes sapphire, for example. In the case in which the plan view shape of the substrate 70 is quadrangular, the length of a side is in a range of 200 μm to 1000 μm, for example. The upper face and the lower face of the substrate 70 are generally parallel to the X-Y plane. The thickness of the substrate 70 is, for example, in a range of 100 μm to 500 μm.

On the substrate 70, a bonding member 72 is disposed. The bonding member 72 is positioned between the substrate 70 and the conductive member 10 in the Z direction. The bonding member 72 is in contact with the substrate 70. The plan view shape of the bonding member 72 is, for example, quadrangular. The upper face and the lower face of the bonding member 72 are generally parallel to the X-Y plane. The bonding member 72 bonds the substrate 70 and the reflecting metal layer 74.

For the bonding member 72, for example, a soldering material having AuSn, NiSn, AgSn or the like as a main component can be used.

On the bonding member 72, a reflecting metal layer 74 is disposed. On the reflecting metal layer 74, the conductive member 10 and the reflecting layer 20 are disposed. A portion of the reflecting metal layer 74 is positioned between the bonding member 72 and the conductive member 10 in the Z direction. Another portion of the reflecting metal layer 74 is positioned between the bonding member 72 and the reflecting layer 20 in the Z direction. The reflecting metal layer 74 is in contact with the bonding member 72. A portion of the reflecting metal layer 74 is in contact with the conductive member 10. Another portion of the reflecting metal layer 74 is in contact with the reflecting layer 20. The plan view shape of the reflecting metal layer 74 is, for example, quadrangular. The upper face and the lower face of the reflecting metal layer 74 are generally parallel to the X-Y plane.

The reflectance of the reflecting metal layer 74 for the peak wavelength of the light emitted by the emission layer 42 is, for example, higher than the reflectance of the conductive member 10 for the peak wavelength of the light emitted by the emission layer 42. The reflectance of the reflecting metal layer 74 for the peak wavelength of the light emitted by the emission layer 42 is, for example, 60% or higher, preferably 70% or higher. For the reflecting metal layer 74, for example, aluminum, gold, platinum, silver, copper, rhodium, ruthenium, or the like can be used.

Variations of the embodiment will be explained below.

FIG. 5 and FIG. 7 to FIG. 10 are plan views schematically showing layouts of the conductive member and the reflecting layer of light emitting elements in first to fifth variations of the embodiment.

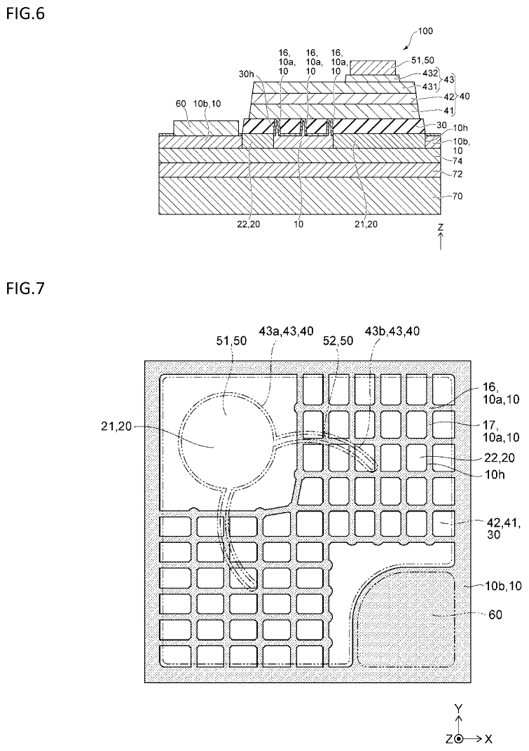

FIG. 6 is a cross-sectional view schematically showing the light emitting element in the first variation of the embodiment.

FIG. 11 is a cross-sectional view schematically showing the light emitting element in the fifth variation of the embodiment.

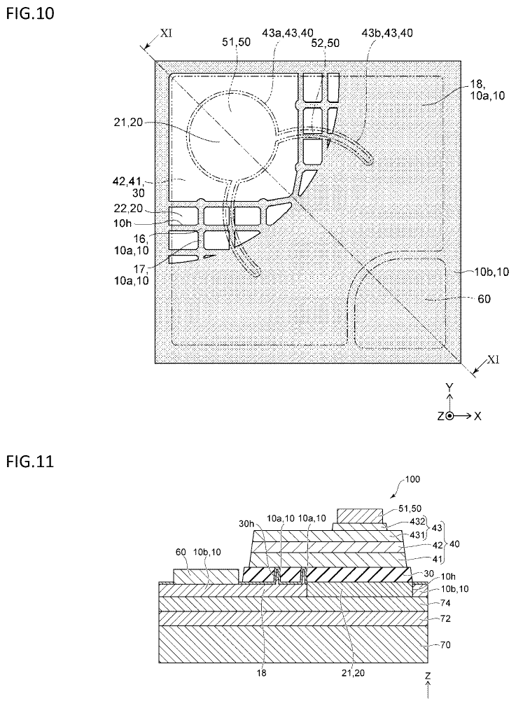

FIG. 11 is a cross-sectional view taken along line XI-XI in FIG. 10.

As shown in FIG. 5 to FIG. 11, in the first to fifth variations, the first region 10a of the conductive member 10 has second portions 17 in addition to the first portions 16 described above. The second portions 17 do not overlap the second through holes 30h in a plan view. The second portions 17 connect adjacent first portions 16 respectively in the X and Y directions. In other words, in the first to fifth variations, the first region 10a of the conductive member 10 is laid out as a grid, grid lines extending in the X and Y directions in a plan view. The intersections of the grid patterned first region 10s overlap the second through holes 30h in a plan view.

Providing the first region 10a of the conductive member 10 not only at locations overlapping the second through holes 30h, but also locations not overlapping the second through holes 30h, allows for the current to spread in the semiconductor structure 40 in a broader range, thereby bringing the current density distribution in the semiconductor structure 40 closer to a uniform distribution.

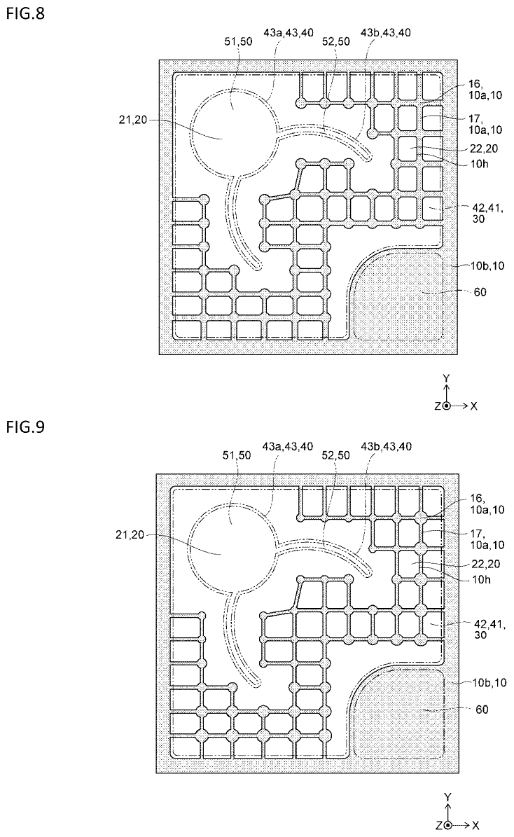

As shown in FIG. 5, FIG. 8, and FIG. 9, in each of the first, third, and fourth variations, the first region 10a of the conductive member 10 is provided only at locations not overlapping the n-electrode 50 and the second layer 432 of the n-type semiconductor layer 43 in a plan view. In contrast, as shown in FIG. 7 and FIG. 10, in the second and fifth variations, the first region 10a of the conductive member 10 is provided at locations overlapping the n-electrode 50 and second layer 432 of the n-type semiconductor 43 in addition to the locations not overlapping the n-electrode 50 and the second layer 432 of the n-type semiconductor layer 43 in a plan view.

Providing the first region 10a of the conductive member 10 at locations overlapping the n-electrode 50 and the second layer 432 of the n-type semiconductor 43 in addition to the locations not overlapping the n-electrode 50 and the second layer 432 of the n-type semiconductor layer 43 can increase the regions where the p-type semiconductor layer 41 and the conductive member 10 are electrically connected to thereby spread current in a broader range in the semiconductor structure 40. This can bring the current density distribution in the semiconductor structure 40 closer to a uniform distribution.

Furthermore, as shown in FIG. 5, FIG. 7, and FIG. 10, in each of the first, second, and fifth variations, the areas of the first portions 16 in a plan view are the same, and the widths of the second portions 17 in a plan view are the same.

Making the plan view areas of the first portions 16 uniform and the plan view widths of the second portions 17 uniform can reduce deviation of the current density distribution in the semiconductor structure 40.

In contrast, as shown in FIG. 8, in the third variation, the areas of the first portions 16 in a plan view are the same, but the widths of the second portions 17 in a plan view are varied. More specifically, in the third variation, the widths of the second portions 17 located near the n-electrode 50 are smaller than the widths of the second portions 17 located near the p-electrode 60 in a plan view. This decreases the percentage of the area the reflecting layer 20 relative to the area of the conductive member 10 per unit area from the n-electrode 50 to the p-electrode 60 in a plan view in the third variation. The widths of the second portions 17 are, for example, in a range of 10 μm to 20 μm.

As shown in FIG. 9, in the fourth variation, the widths of the second portions 17 in a plan view are the same, but the areas of the first portions 16 in a plan view are varied. More specifically, in the fourth variation, the plan view areas of the first portions 16 increase from the n-electrode 50 to the p-electro 60. This decreases the percentage of the area of reflecting layer 20 relative to the area of the conductive member 10 per unit area from the n-electrode 50 to the p-electrode 60 in a plan view in the fourth variation.

As shown in FIG. 10 and FIG. 11, in the fifth variation, the first region 10a of the conducive member 10 has a third portion 18 in addition to the first portions 16 and the second portions 17 described above. The third portion 18 has no first through hole 10h. In the fifth variation, the first portions 16 and the second portions 17 are provided at locations that are near the n-electrode 50, and the third portion 18 is provided at a location that is near the p-electrode 60. In other words, in the fifth variation, the reflecting layer 20 is provided only at a location that is near the n-electrode 50, and not provided near the p-electrode 60. This decreases the percentage of the aera of the reflecting layer 20 relative to the area of the conductive member 10 per unit area from the n-electrode 50 to the p-electrode 60 in a plan view in the fifth variation. Decreasing the percentage of the area of the reflecting layer 20 relative to the area of the conductive member 10 per unit area from the n-electrode 50 to the p-electrode 60 in a plan view as described above allows the current to readily spread at a location distant from the n-type electrode 50 while allowing the reflecting layer 20 to increase the light extraction efficiency at a location close to the n-electrode 50.

### Method of Manufacturing Light Emitting Element

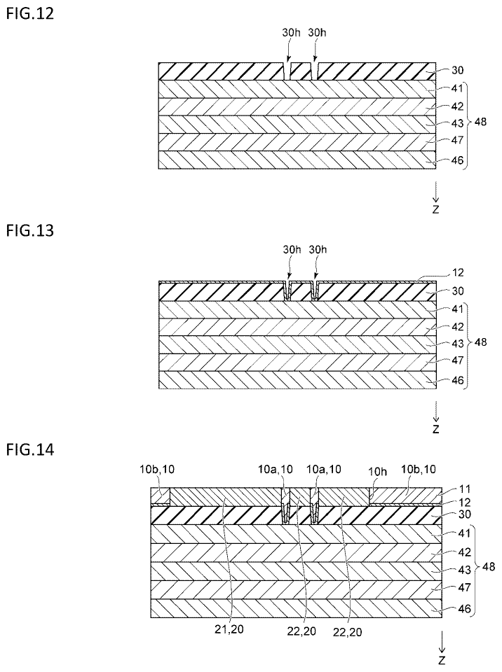

FIG. 12 to FIG. 17 are cross-sectional views schematically showing a method of manufacturing a light emitting element according to an embodiment.

The steps shown in FIG. 12 to FIG. 15 are performed, for example, in the state in which the up-down direction is reversed from that shown in FIG. 3. The steps shown in FIG. 16 and FIG. 17 are performed, for example, in the state in which the up-down direction is the same as that shown in FIG. 3. The up-down direction in each of these steps is not limited to this.

In the method of manufacturing a light emitting element according to this embodiment, a stack structure 48 is prepared, and then an insulation layer 30 is formed on the stack structure 48 as shown in FIG. 12.

The stack structure 48 has a first base 46, a second base 47 positioned on the first base 46, an n-type semiconductor layer 43 positioned on the second base 47, an emission layer 42 positioned on the n-type semiconductor layer 43, and a p-type semiconductor layer 41 positioned on the emission layer 42. The first base 46 is, for example, a substrate which contains GaAs (gallium arsenide). The second base 47 is, for example, a semiconductor layer containing GaInP (gallium indium phosphide).

Subsequent to preparing the stack structure 48, an insulation layer 30 having second through holes 30h is formed on the p-type semiconductor layer 41 of the stack structure 48. The insulation layer having second through holes 30h can be formed by forming an insulation layer 30 on the p-type semiconductor layer 41 followed by creating second through holes 30h at certain locations of the insulation layer 30.

In the method of manufacturing a light emitting element according to this embodiment, a step of forming a second conductive layer 12 on the insulation layer 30 as shown in FIG. 13 is performed next. A portion of the second conductive layer 12 is formed in contact with the p-type semiconductor layer 41 in the second through holes 30h.

In the method of manufacturing a light emitting element according to this embodiment, a step of forming a first conductive layer 11 on the second conductive layer 12 as shown in FIG. 14 is performed next. This is followed by a step of forming a first through hole 10h which exposes the insulation layer 30 by removing a portion of the first conductive layer 11 and a portion of the second conductive layer 12. Furthermore, a step of forming a reflecting layer 20 in the first through hole 10h so as to be in contact with the insulation layer 30 is performed.

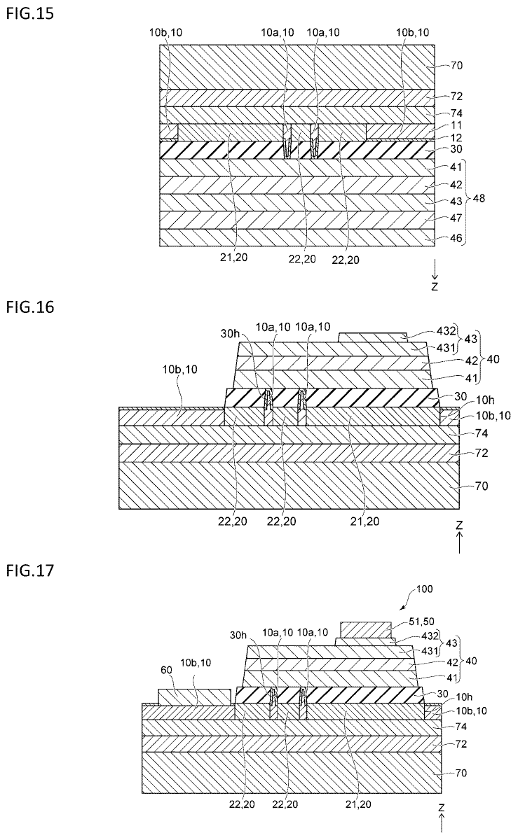

In the method of manufacturing a light emitting element according to this embodiment, a step of forming a reflecting metal layer 74 on the first conductive layer 11 and the reflecting layer 20 as shown in FIG. 15 is performed next. Then a bonding member 72 is formed on the reflecting metal layer 74. Then the reflecting metal layer 74 and the substrate 70 are bonded using the bonding member 72.

In the method of manufacturing a light emitting element according to this embodiment, a step of removing the first base 46 and the second base 47, as well as a portion of the n-type semiconductor layer 43, a portion of the emission layer 42, a portion of the p-type semiconductor layer 41, and a portion of the insulation layer 30 as shown in FIG. 16 is performed next. By following these steps, a semiconductor structure 40 which includes an n-type semiconductor layer 43 including a first layer 431 and a second layer 432, an emission layer 42, and a p-type semiconductor layer 41 is formed.

In the method of manufacturing a light emitting element according to this embodiment, a step of forming an n-electrode 50 on the n-type semiconductor layer 43 as shown in FIG. 17 is performed next. This is followed by a step of removing a portion of the second conductive layer 12 and forming a p-electrode 60 on the first conductive layer 11. In the manner described above, a light emitting element 100 is manufactured.

The first conductive layer 11, the second conductive layer 12, the reflecting layer 20, the insulation layer 30, the n-electrode 50, the p-electrode 60, and the reflecting metal layer 74 can be formed by, for example, sputtering or vapor deposition. The removal of the insulation layer 30, the first conductive layer 11, and the second conductive layer 12 can be accomplished by, for example, dry etching or wet etching. For the removal of the first base 46 and the second base 47, wet etching can be used. For the removal of the p-type semiconductor layer 41, the emission layer 42, and the n-type semiconductor layer 43, for example, dry etching or wet etching can be employed.

What is claimed is:

1. A light emitting element comprising:
a conductive member having a first through hole;
a reflecting layer disposed in the first through hole;
an insulation layer disposed on the conductive member and the reflecting layer and having second through holes positioned so as not to overlap the first through hole in a plan view;
a semiconductor structure comprising a p-type semiconductor layer disposed on the insulation layer, an emission layer disposed on the p-type semiconductor layer, and an n-type semiconductor layer disposed on the emission layer in part;
an n-electrode disposed on and electrically connected to the n-type semiconductor layer; and
p-electrode electrically connected to the conductive member, wherein:
a reflectance of the reflecting layer for a peak wavelength of light emitted from the emission layer is higher than the reflectance of the conductive member for the peak wavelength of the light emitted from the emission layer,
a portion of the conductive member is in contact with the p-type semiconductor layer in the second through holes, and
at least one portion of the reflecting layer overlaps the emission layer in a plan view.

2. The light emitting element according to claim 1, wherein the reflecting layer comprises a first reflecting portion overlapping the n-electrode in a plan view, and a second reflecting portion not overlapping the n-electrode in a plan view.

3. The light emitting element according to claim 2, wherein:
The n-electrode comprises a pad portion, and an extended portion extending from the pad portion;
the n-type semiconductor layer comprises a first semiconductor portion overlapping the pad portion in a plan view, and a second semiconductor portion overlapping the extended portion in a plan view; and
the first reflecting portion overlaps the pad portion and the extended portion in a plan view.

4. The light emitting element according to claim 1, wherein:
the conductive member has a first region overlapping the semiconductor structure in a plan view, and a second region not overlapping the semiconductor structure in a plan view;
the p-electrode is disposed in the second region; and
a percentage of an area of the reflecting layer relative to an area of the conductive member per unit area decreases from the n-electrode to the p-electrode in a plan view.

5. The light emitting element according to claim 2, wherein:
the conductive member has a first region overlapping the semiconductor structure in a plan view, and a second region not overlapping the semiconductor structure in a plan view;
the p-electrode is disposed in the second region; and
a percentage of an area of the reflecting layer relative to an area of the conductive member per unit area decreases from the n-electrode to the p-electrode in a plan view.

6. The light emitting element according to claim 3, wherein:
the conductive member has a first region overlapping the semiconductor structure in a plan view, and a second region not overlapping the semiconductor structure in a plan view;
the p-electrode is disposed in the second region; and
a percentage of an area of the reflecting layer relative to an area of the conductive member per unit area decreases from the n-electrode to the p-electrode in a plan view.

7. The light emitting element according to claim 1, wherein the reflecting layer is a dielectric multilayer film.

8. The light emitting element according to claim 2, wherein the reflecting layer is a dielectric multilayer film.

9. The light emitting element according to claim 3, wherein the reflecting layer is a dielectric multilayer film.

10. The light emitting element according to claim 1, further comprising:
a substrate;
a bonding member positioned between the substrate and the conductive member; and
a reflecting metal layer positioned between the bonding member and the conductive member.

11. The light emitting element according to claim 2, further comprising:
a substrate;
a bonding member positioned between the substrate and the conductive member; and
a reflecting metal layer positioned between the bonding member and the conductive member.

12. The light emitting element according to claim 3, further comprising:
a substrate;
a bonding member positioned between the substrate and the conductive member; and
a reflecting metal layer positioned between the bonding member and the conductive member.

13. The light emitting element according to claim 1, wherein:
the conductive member comprises a first conductive layer containing gold, and a second conductive layer disposed on the first conductive layer and containing indium tin oxide;
the first conductive layer is electrically connected to the p-electrode; and
the second conductive layer is electrically connected to the p-type semiconductor layer.

14. The light emitting element according to claim 2, wherein:
the conductive member comprises a first conductive layer containing gold, and a second conductive layer disposed on the first conductive layer and containing indium tin oxide;
the first conductive layer is electrically connected to the p-electrode; and
the second conductive layer is electrically connected to the p-type semiconductor layer.

15. The light emitting element according to claim 3, wherein:
the conductive member comprises a first conductive layer containing gold, and a second conductive layer disposed on the first conductive layer and containing indium tin oxide;
the first conductive layer is electrically connected to the p-electrode; and
the second conductive layer is electrically connected to the p-type semiconductor layer.

16. The light emitting element according to claim 1, wherein:
the p-type semiconductor layer contains GaP;
the n-type semiconductor layer contains GaAs; and
the emission layer contains AlGaInP.

17. The light emitting element according to claim 1, wherein:
the p-type semiconductor layer contains GaP;
the n-type semiconductor layer contains GaAs; and
the emission layer contains AlGaInP.

18. The light emitting element according to claim 1, wherein:
the p-type semiconductor layer contains GaP;
the n-type semiconductor layer contains GaAs; and
the emission layer contains AlGaInP.
